(19) United States
(12) Patent Application Publication
(10) Pub. No.: US 2024/0243125 A1
(43) Pub. Date: Jul. 18, 2024

(54) INTEGRATED CIRCUIT DEVICES

(71) Applicant: Samsung Electronics Co., Ltd., Suwon-si (KR)

(72) Inventors: Seongyul PARK, Suwon-si (KR); Myoungho KANG, Suwon-si (KR); Changhyeon LEE, Suwon-si (KR); Yeazi HEO, Suwon-si (KR)

(73) Assignee: Samsung Electronics Co., Ltd., Suwon-si (KR)

(21) Appl. No.: 18/538,369

(22) Filed: Dec. 13, 2023

(30) Foreign Application Priority Data
Jan. 12, 2023 (KR) 10-2023-0004979

(51) Int. Cl. H01L 27/088

(52) U.S. Cl. CPC H01L 27/088; H01L 27/0886

(57) ABSTRACT

An integrated circuit device may include fin-type active regions protruding from a surface of a substrate and extending in a first horizontal direction, at least one gate pillar on the substrate and extending in the first horizontal direction, and a plurality of gate groups arranged in a second horizontal direction on the plurality of fin-type active regions. Each of the plurality of gate groups may include a plurality of gate patterns spaced apart from each other in the second horizontal direction. Each of the plurality of gate patterns may extend in the second horizontal direction. The plurality of gate patterns each may include at least one dummy gate pattern on at least one end of a corresponding one of the plurality of gate groups in the second horizontal direction. The at least one dummy gate pattern may be in contact with and connected to the at least one gate pillar.

### CROSS-REFERENCE TO RELATED APPLICATION

This application is based on and claims priority under 35 U.S.C. § 119 to Korean Patent Application No. 10-2023-0004979, filed on Jan. 12, 2023 in the Korean Intellectual Property Office, the disclosure of which is incorporated by reference herein in its entirety.

### BACKGROUND

Inventive concept relate to an integrated circuit device, and more particularly, to an integrated circuit device having a metal gate.

As the degree of integration of integrated circuit devices has increased, the size of such devices has been reduced. Accordingly, to further improve the performance of integrated circuit devices, an integrated circuit device in which the polysilicon gate was replaced with a metal gate containing metal has been introduced. To form a metal gate, a replacement metal gate (RMG) process may be used to form a metal gate in a space where a previously formed one-time gate was removed.

### SUMMARY

Inventive concepts provide an integrated circuit device having a metal gate and allowing for increasing the degree of integration.

According to an embodiment of inventive concepts, an integrated circuit device may include a substrate including a plurality of fin-type active regions, the plurality of fin-type active regions protruding from a surface of the substrate and extending in a first horizontal direction; at least one gate pillar on the substrate and extending in the first horizontal direction; and a plurality of gate groups arranged in a second horizontal direction on the plurality of fin-type active regions. The second horizontal direction may be orthogonal to the first horizontal direction. Each of the plurality of gate groups may include a plurality of gate patterns spaced apart from each other in the second horizontal direction. Each of the plurality of gate patterns may extend in the second horizontal direction. The plurality of gate patterns each may include at least one dummy gate pattern on at least one end of a corresponding one of the plurality of gate groups in the second horizontal direction. The at least one dummy gate pattern may be in contact with and connected to the at least one gate pillar.

According to an embodiment of inventive concepts, an integrated circuit device may include a substrate including a plurality of fin-type active regions, the plurality of fin-type active regions protruding from a surface of the substrate and extending in a first horizontal direction; a nanosheet stacked structure including a plurality of nanosheets extending parallel to upper surfaces of each of the plurality of fin-type active regions, the plurality of nanosheets respectively having channel regions at positions spaced apart from the upper surfaces of the plurality of fin-type active regions; a first gate pillar and a second gate pillar on the substrate, the first gate pillar and the second gate pillar extending in the first horizontal direction and being spaced apart from each other in a second horizontal direction, the second horizontal direction being orthogonal to the first horizontal direction; and a first functional block including a plurality of first gate patterns on the plurality of fin-type active regions, the plurality of first gate patterns being spaced apart from each other in the second horizontal direction between the first gate pillar and the second gate pillar and extending in the second horizontal direction. The plurality of first gate patterns may include first dummy gate patterns contacting and connected to the first gate pillar and second dummy gate patterns contacting and connected to the second gate pillar.

According to an embodiment of inventive concepts, an integrated circuit device may include a substrate including a plurality of fin-type active regions, the plurality of fin-type active regions protruding from a surface of the substrate and extending in a first horizontal direction; a nanosheet stacked structure including a plurality of nanosheets extending parallel to upper surfaces of each of the plurality of fin-type active regions, and the plurality of nanosheets having channel regions at positions spaced apart from the upper surfaces of the plurality of fin-type active regions; a first gate pillar and a second gate pillar on the substrate, the first gate pillar and the second gate pillar extending in the first horizontal direction and being spaced apart from each other in a second horizontal direction, the second horizontal direction orthogonal to the first horizontal direction; a plurality of gate groups arranged in the second horizontal direction on the plurality of fin-type active regions, the plurality of gate groups including a plurality of gate patterns spaced apart from each other in the second horizontal direction between the first gate pillar and the second gate pillar, and the plurality of gate patterns extending in the second horizontal direction; and a first edge dummy pattern and a second edge dummy pattern extending in the second horizontal direction at both sides of the plurality of gate groups in the first horizontal direction. In each of the plurality of gate groups, the plurality of gate patterns may include a first dummy gate pattern and a second dummy gate pattern. The first dummy gate pattern may be connected to and in contact with the first gate pillar to form an integral body. The second dummy gate pattern may be integrally connected to and in contact with the second gate pillar. Both ends of each of the plurality of gate groups in the second horizontal direction may include the first dummy gate pattern. Each of the plurality of gate patterns may have a first width in the first horizontal direction. Each of the first gate pillar and the second gate pillar may have a second width in the second horizontal direction. The second width may be greater than the first width.

### BRIEF DESCRIPTION OF THE DRAWINGS

Embodiments will be more clearly understood from the following detailed description taken in conjunction with the accompanying drawings in which:

FIGS. 1A to 1C are planar arrangement views and partially enlarged views illustrating an integrated circuit device according to embodiments of inventive concepts;

FIG. 2 is a plan layout view illustrating an integrated circuit device according to embodiments of inventive concepts;

FIG. 3 is a plan layout view illustrating an integrated circuit device according to embodiments of inventive concepts;

FIGS. 4A and 4B are planar arrangement views and partially enlarged views illustrating an integrated circuit device according to embodiments of inventive concepts;

FIGS. 5 to 15 are cross-sectional views for explaining a method of manufacturing an integrated circuit device according to embodiments of inventive concepts;

FIGS. 16A to 16E are cross-sectional views illustrating an integrated circuit device according to embodiments of inventive concepts;

FIG. 17 is a cross-sectional view illustrating an integrated circuit device according to embodiments of inventive concepts; and

FIG. 18 is a flowchart illustrating a process of manufacturing an integrated circuit device according to embodiments of inventive concepts.

### DETAILED DESCRIPTION

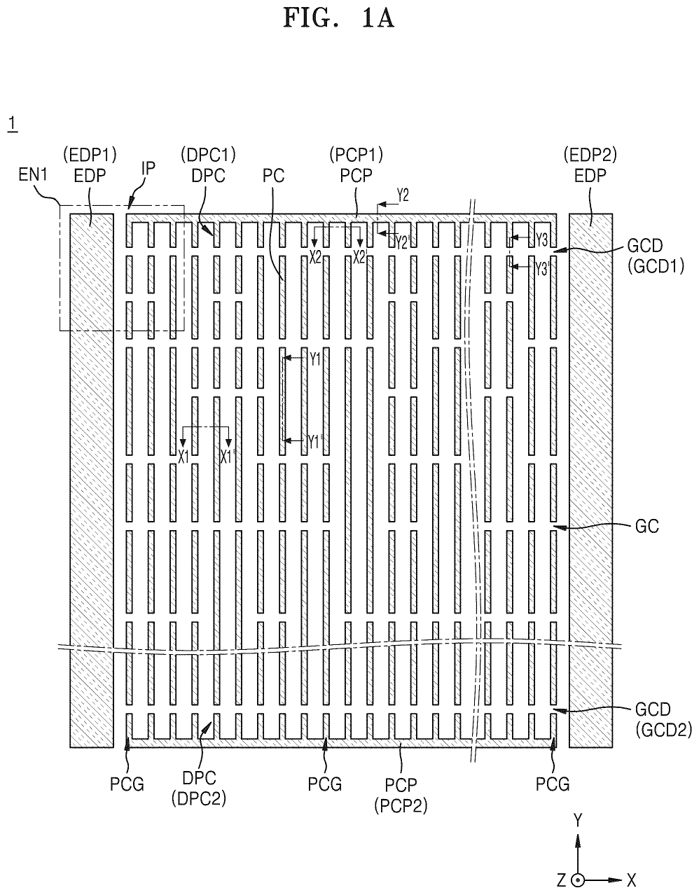

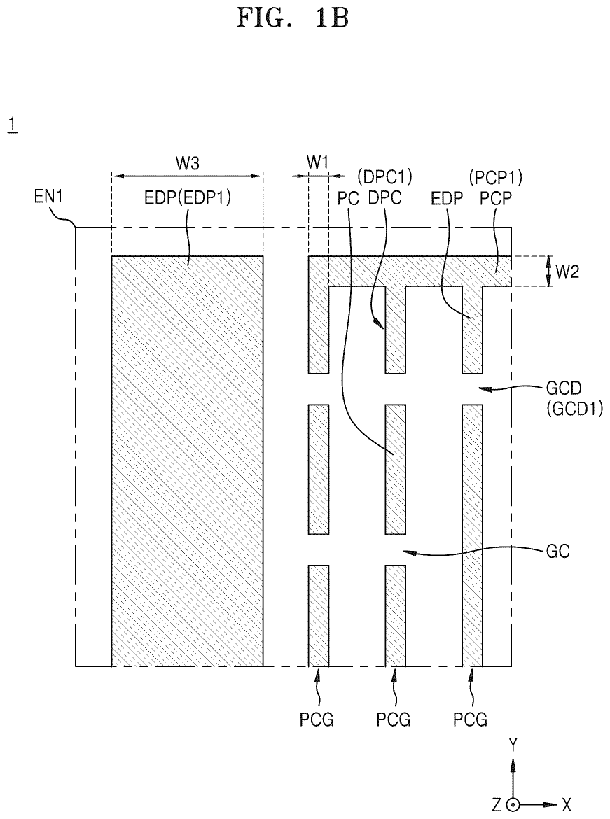

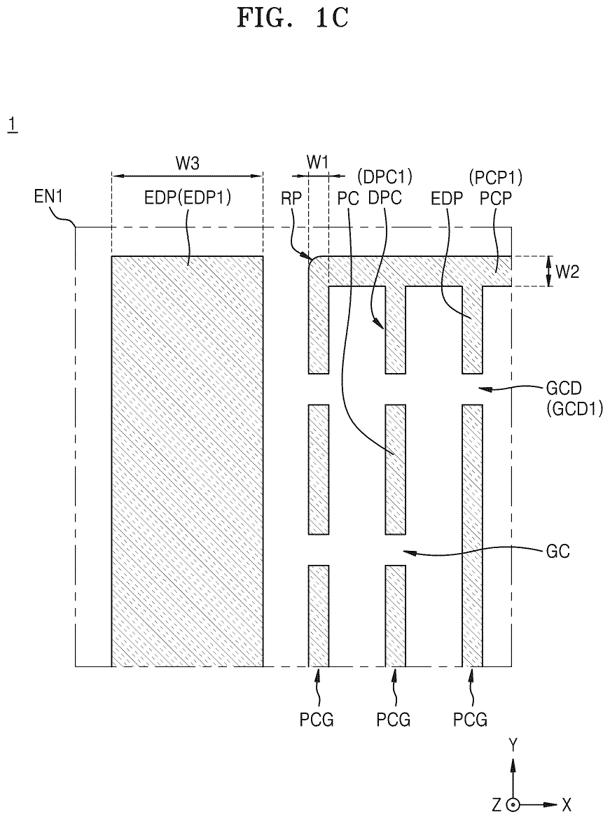

FIGS. 1A to 1C are planar arrangement views and partially enlarged views illustrating an integrated circuit device according to embodiments of inventive concepts. FIGS. 1B and 1C are planar arrangement views illustrating an enlarged portion EN1 of FIG. 1A.

Referring to FIG. 1A, the integrated circuit device 1 may include a pair of gate pillars PCP extending along a first horizontal direction (X direction) and being spaced apart from each other in a second horizontal direction (Y direction) orthogonal to the first horizontal direction (X direction), and a plurality of gate groups PCG spaced apart from each other in a first horizontal direction (X direction) between a pair of gate pillars PCP and disposed along a second horizontal direction (Y direction). The pair of gate pillars PCP spaced apart from each other in the second horizontal direction (Y direction) may include a first gate pillar PCP1 and a second gate pillar PCP2.

Each of the plurality of gate groups PCG may include a plurality of gate patterns PC disposed on a straight line extending in the second horizontal direction (Y direction) between the first gate pillar PCP1 and the second gate pillar PCP2. Each of the plurality of gate patterns PC may extend in the second horizontal direction (Y direction). Among the plurality of gate patterns PC, two gate patterns PC adjacent to each other in the second horizontal direction (Y direction) may be spaced apart from each other in the second horizontal direction (Y direction). A gate cut region GC may be defined between two gate patterns PC adjacent to each other in the second horizontal direction (Y direction) among the plurality of gate patterns PC. A plurality of gate cut regions GC may be disposed between the first gate pillar PCP1 and the second gate pillar PCP2. Each of the plurality of gate cut regions GC may extend in the first horizontal direction (X direction).

A plurality of gate patterns PC included in one gate group PCG may include at least two dummy gate patterns DPC. Among the plurality of gate patterns PC included in one gate group PCG, each of the two gate patterns PC positioned at both ends in the second horizontal direction (Y direction) may be a dummy gate pattern DPC. Dummy gate patterns DPC positioned at one end of a plurality of gate groups PCG may be contacted and connected to a first gate pillar PCP1 of the pair of gate pillars PCP, and dummy gate patterns DPC positioned at the other end of the plurality of gate groups PCG may be contacted and connected to the second gate pillar PCP2 of the pair of gate pillars PCP. The first gate pillar PCP1 and the dummy gate patterns DPC contacting and connected to the first gate pillar PCP1 may be integrally formed. The second gate pillar PCP2 and the dummy gate patterns DPC contacting and connected to the second gate pillar PCP2 may be integrally formed.

The dummy gate patterns DPC may include first dummy gate patterns DPC1 and second dummy gate patterns DPC2. Dummy gate patterns DPC connected to the first gate pillar PCP1 may be first dummy gate patterns DPC1, and dummy gate patterns DPC connected to the second gate pillar PCP2 may be second dummy gate patterns DPC2. That is, the plurality of gate patterns PC included in one gate group PCG include a first dummy gate pattern DPC1 and a second dummy gate pattern DPC2, and among the plurality of gate patterns PC included in one gate group PCG, a gate pattern PC positioned at one end of one gate group PCG may be a first dummy gate pattern DPC1, and a gate pattern PC positioned at the other end may be the second dummy gate pattern DPC2. The first gate pillar PCP1 and the plurality of first dummy gate patterns DPC1 may be integrally formed, and the second gate pillar PCP2 and the plurality of second dummy gate patterns DPC2 may be integrally formed.

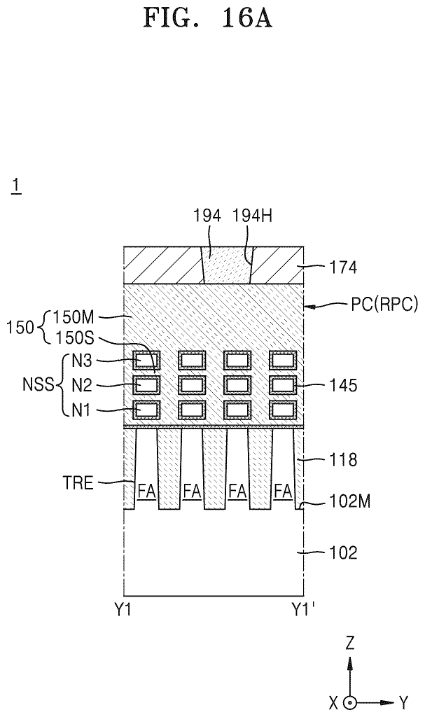

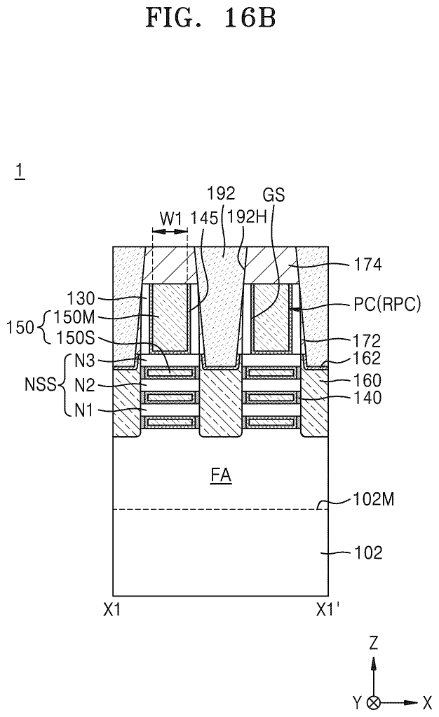

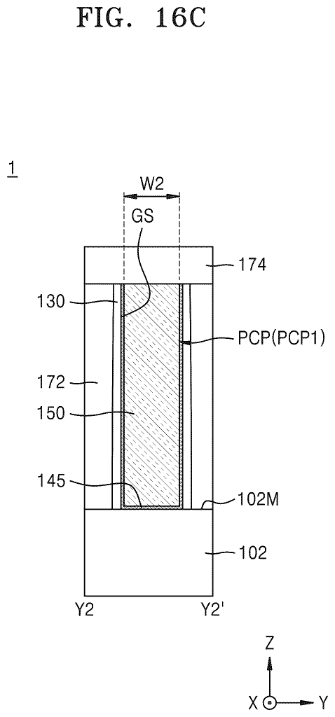

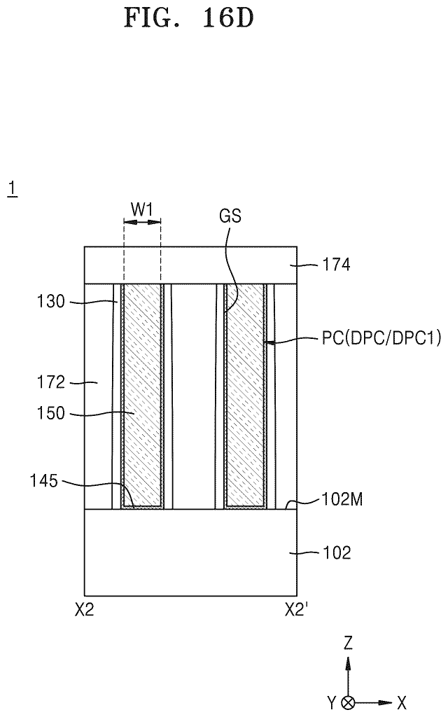

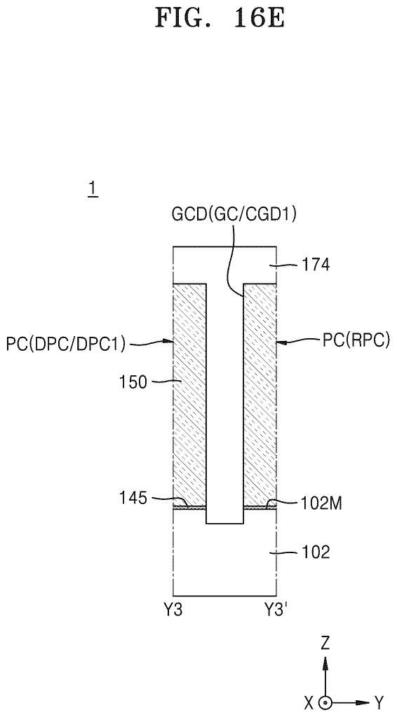

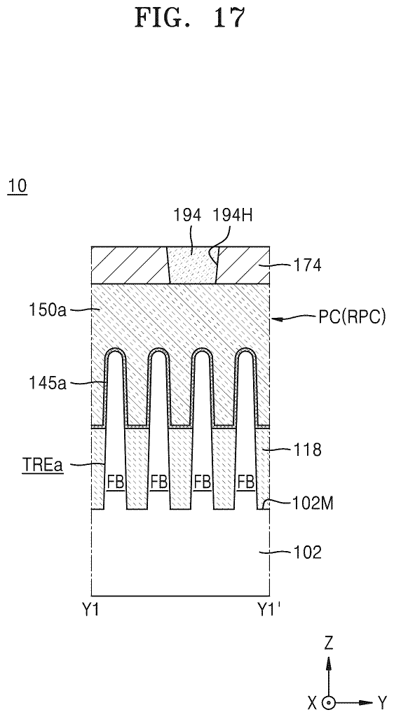

Among the plurality of gate patterns PC included in one gate group PCG, at least some of the gate patterns PC disposed between the first dummy gate pattern DPC1 and the second dummy gate pattern DPC2 may be circuit gate patterns (RPC of FIG. 16A or RPC of FIG. 17). The circuit gate pattern RPC may cross the fin-type active region FA shown in FIG. 16A and is connected to the second contact plug 194 shown in FIG. 16A, or cross the fin-type active region FA shown in FIG. 17 and be connected to the second contact plug 194 shown in FIG. 17.

Among the plurality of gate patterns PC included in one gate group PCG, each of the gate patterns PC disposed between the first dummy gate pattern DPC1 and the second dummy gate pattern DPC2 may be a circuit gate pattern RPC (see e.g., RPC in FIG. 16A), but is not limited thereto. For example, among a plurality of gate patterns PC included in one gate group PCG, at least one of the gate patterns PC disposed between the first dummy gate pattern DPC1 and the second dummy gate pattern DPC2 may be the dummy gate pattern DPC, and this may be variously modified according to the configuration of the logic circuit included in the integrated circuit device 1.

At least one edge dummy pattern EDP extending in the second horizontal direction (Y direction) may be disposed on at least one side of the plurality of gate groups PCG in the first horizontal direction (X direction). In some embodiments, edge dummy patterns EDP may be disposed on both sides of each of the plurality of gate groups PCG in the first horizontal direction (X direction). For example, a plurality of gate groups PCG may be disposed between a pair of edge dummy patterns EDP spaced apart in a first horizontal direction (X direction). At least one edge dummy pattern EDP may be spaced apart from each of the plurality of gate patterns PC included in the plurality of gate groups PCG and each of a pair of gate pillars PCP.

The pair of edge dummy patterns EDP may include a first edge dummy pattern EDP1 and a second edge dummy pattern EDP2. Among the pair of edge dummy patterns EDP, one located on one side of the plurality of gate groups PCG in the first horizontal direction (X direction) may be the first edge dummy pattern EDP1, and another one located on the other side may be the second edge dummy pattern EDP2. Although FIG. 1A shows that one edge dummy pattern EDP is disposed on one side and the other side of the plurality of gate groups PCG in the first horizontal direction (X direction), inventive concepts is not limited thereto. In some embodiments, two or more edge dummy patterns EDP spaced apart from each other in the first horizontal direction (X direction) may be disposed on each of one side and the other side of the plurality of gate groups PCG in the first horizontal direction (X direction). The first edge dummy pattern EDP1, the first gate pillar PCP1, the second edge dummy pattern EDP2, and the second gate pillar PCP2 are sequentially spaced apart from each other and disposed to surround the plurality of gate patterns PC. The first edge dummy pattern EDP1, the first gate pillar PCP1, the second edge dummy pattern EDP2, and the plurality of gate patterns PC surrounded by the second gate pillar PCP2 may constitute one functional block IP. A functional block is also called Intellectual Property (IP), and refers to a unit block divided into functional units that may be actually developed. For example, the integrated circuit device 1 may include a plurality of functional blocks IP, and each functional block IP may be surrounded by a first edge dummy pattern EDP1, a first gate pillar PCP1, a second edge dummy pattern EDP2, and a second gate pillar PCP2. In some embodiments, the functional block IP may have a rectangular shape in plan view.

Among the plurality of gate cut regions GC disposed between the first gate pillar PCP1 and the second gate pillar PCP2, gate cut regions GC adjacent to the first dummy gate patterns DPC1 and the second dummy gate patterns DPC2 may be referred to as dummy gate cut regions GCD. The dummy gate cut regions GCD may include a first dummy gate cut region GCD1 and a second dummy gate cut region GCD2. The first dummy gate cut region GCD1 may be limited between the first dummy gate patterns DPC1 connected to the first gate pillar PCP1 and the gate patterns PC adjacent to the first dummy gate patterns DPC1 in the second horizontal direction (Y direction). The second dummy gate cut region GCD2 may be limited between the second dummy gate patterns DPC2 connected to the second gate pillar PCP2 and the gate patterns PC adjacent to the second dummy gate patterns DPC2 in the second horizontal direction (Y direction).

The dummy gate cut region GCD may cross all of the plurality of gate groups PCG disposed between the first edge dummy pattern EDP1 and the second edge dummy pattern EDP2 and extend in the first horizontal direction (X direction). One ends of the first dummy gate patterns DPC1 are connected to and in contact with the first gate pillar PCP1, and other ends of the first dummy gate patterns DPC1 may contact and be disconnected from the first dummy gate cut region GCD1. One ends of the second dummy gate patterns DPC2 are connected to and in contact with the second gate pillar PCP2, and other ends of the second dummy gate patterns DPC2 may contact and be disconnected from the second dummy gate cut region GCD2. That is, the first dummy gate cut region GCD1 may contact the other ends of the first dummy gate patterns DPC1 of all of the plurality of gate groups PCG disposed between the first edge dummy pattern EDP1 and the second edge dummy pattern EDP2, and the second dummy gate cut region GCD2 may contact other ends of second dummy gate patterns DPC2 of all of the plurality of gate groups PCG disposed between the first edge dummy pattern EDP1 and the second edge dummy pattern EDP2.

Since the first dummy gate patterns DPC1 included in the plurality of gate groups PCG are disposed between the first gate pillar PCP1 extending in the first horizontal direction (X direction) and the first dummy gate cut region GCD1 extending in the first horizontal direction (X direction), all may have the same extension length in the second horizontal direction (Y direction). Since the second dummy gate patterns DPC2 included in the plurality of gate groups PCG are disposed between the second gate pillar PCP2 extending in the first horizontal direction (X direction) and the second dummy gate cut region GCD2 extending in the first horizontal direction (X direction), all may have the same extension length in the second horizontal direction (Y direction). That is, all of the dummy gate patterns DPC connected to and in contact with one gate pillar PCP may have the same extension length in the second horizontal direction (Y direction). The extension lengths of the first dummy gate patterns DPC1 and the extension lengths of the second dummy gate patterns DPC2 may be equal to each other, but are not limited thereto. For example, one of the extension lengths of the first dummy gate patterns DPC1 and the extension lengths of the second dummy gate patterns DPC2 may have a greater value than the other one.

Among a plurality of gate cut regions GC, at least some of the gate cut regions GC other than the first dummy gate cut region GCD1 and the second dummy gate cut region GCD2 may extend in a first horizontal direction (X direction) while crossing only some of the plurality of gate groups PCG disposed between the first edge dummy pattern EDP1 and the second edge dummy pattern EDP2, and this may be variously modified according to the configuration of the logic circuit included in the integrated circuit device 1.

Referring to FIGS. 1A and 1B together, the gate pattern PC may have a first width W1 in a first horizontal direction (X direction), and the gate pillar PCP may have a second width W2 in a second horizontal direction (Y direction). The second width W2 may be less than the first width W1. In some embodiments, the second width W2 may have a value greater than the first width W1 and less than twice the first width W1. For example, the first width W1 may be several nm. The edge dummy pattern EDP may have a third width W3 in the first horizontal direction (X direction). The third width W3 may have a greater value than each of the first and second widths W1 and W2. In some embodiments, the third width W3 may have a value at least three times greater than the first width W1. For example, the third width W3 may be several nm to several tens of nm.

Referring to FIGS. 1A and 1C together, the gate pillar PCP may have a planar shape having a round portion RP. For example, in a planar shape, among two corners of the edge of the gate pillar PCP facing the edge dummy pattern EDP, the corner opposite to the dummy gate pattern DPC may have a round portion RP.

Referring to FIGS. 1A to 1C together, a plurality of gate patterns PC, a pair of gate pillars PCP, and at least one edge dummy pattern EDP may be formed together and made of the same material. Each of the plurality of gate patterns PC, the pair of gate pillars PCP, and at least one edge dummy pattern EDP may be any one of the plurality of gate electrode layers 150 shown in FIGS. 16A to 16E.

For example, the plurality of gate patterns PC, a pair of gate pillars PCP, and at least one edge dummy pattern EDP may include a metal-containing layer for adjusting the work function and a metal-containing layer for filling a gap filling a space above the metal-containing layer for adjusting the work function. The work function metal-containing layer may include at least one metal selected from the group consisting of Ti, W, Ru, Nb, Mo, Hf, Ni, Co, Pt, Yb, Tb, Dy, Er, and Pd. In some embodiments, a plurality of gate patterns PC, a pair of gate pillars PCP, and at least one edge dummy pattern EDP may have a structure in which a metal nitride layer, a metal layer, a conductive capping layer, and a gap-fill metal film are sequentially stacked. The metal nitride layer and the metal layer may include at least one metal selected from the group consisting of Ti, Ta, W, Ru, Nb, Mo, or Hf. The gap-fill metal film may be formed of a W film or an Al film. In some embodiments, a plurality of gate patterns PC, a pair of gate pillars PCP, and at least one edge dummy pattern EDP may include a TiAlC/TiN/W stack structure, a TiN/TaN/TiAlC/TiN/W stack structure, or a TiN/TaN/TiN/TiAlC/TiN/W stack structure but are not limited to the above examples.

FIGS. 1A to 1C show a distance between two gate patterns PC adjacent to each other in a first horizontal direction (X direction) greater than the first width W1 among the plurality of gate patterns PC, but this is for convenience, and is not limited thereto. In some embodiments, a distance between two adjacent gate patterns PC among the plurality of gate patterns PC in the first horizontal direction (X direction) may be equal to the first width W1. In some embodiments, a distance between two adjacent gate patterns PC among the plurality of gate patterns PC in the first horizontal direction (X direction) may be less than the first width W1.

In relation to a plurality of gate groups PCG included in the integrated circuit device 1 according to embodiments of inventive concepts, after first forming a plurality of line patterns, a first gate pillar PCP1 connected to and in contact with one end of the plurality of line patterns, and a second gate pillar PCP2 connected to and in contact with other ends of the plurality of line patterns, by gate cut regions GC formed by removing portions of the plurality of line patterns, each of the plurality of gate groups PCG may be separated into a plurality of gate patterns PC. First dummy gate patterns DPC1 separated from ends of the plurality of line patterns may be formed to be in contact with and connected to a first gate pillar PCP1, and second dummy gate patterns DPC2 separated from the other ends of the plurality of line patterns may be formed to contact and be connected to the second gate pillar PCP2.

When the degree of integration of the integrated circuit device increases, as the plurality of line patterns are miniaturized, an aspect ratio, e.g., a ratio between a width and a height of each of the plurality of line patterns, increases, thereby increasing a possibility of occurrence of leaning in the plurality of line patterns.

When leaning occurs in the plurality of line patterns, a bridge occurs between adjacent gate patterns PC among the plurality of gate patterns PC formed by separating the plurality of line patterns, or a bridge occurs between the gate pattern PC and another component adjacent to the gate pattern PC, for example, the source/drain region shown in FIG. 16, or the second contact plug 194 shown in FIG. 16A is not connected to the circuit gate pattern RPC shown in FIG. 16A.

However, in the process of forming the integrated circuit device 1 according to embodiments of inventive concepts, since the plurality of line patterns, the first gate pillar PCP1, and the second gate pillar PCP2 are formed together, both ends of the plurality of line patterns are connected to the first gate pillar PCP1 and the second gate pillar PCP2 so that leaning may not occur. Therefore, the integrated circuit device 1 according to embodiments of inventive concepts may limit and/or prevent problems caused by leaning from occurring, and may increase the degree of integration.

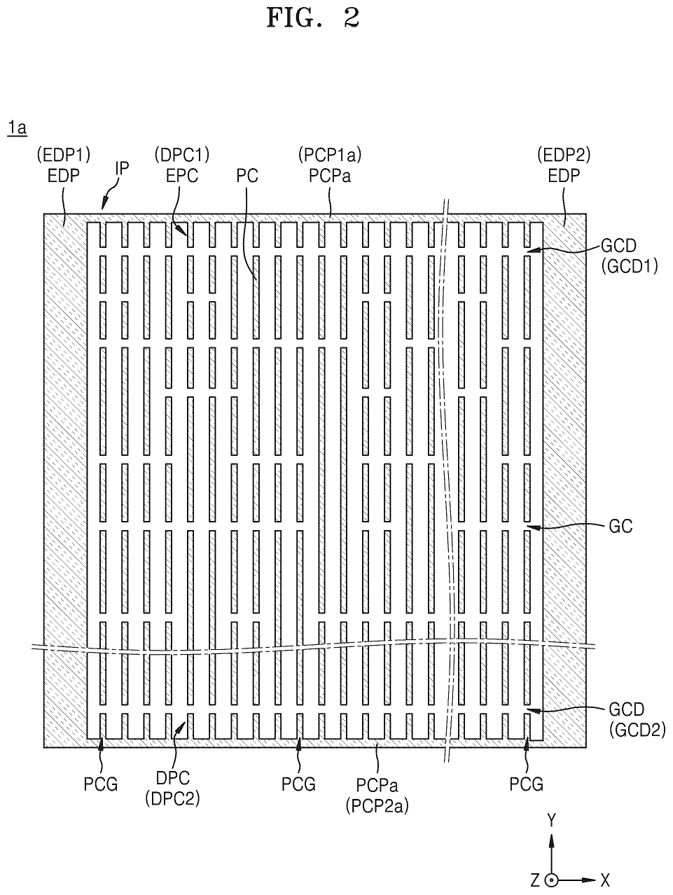

FIG. 2 is a plan layout view illustrating an integrated circuit device according to embodiments of inventive concepts. Among the contents of FIG. 2, descriptions overlapping those of FIGS. 1A to 1C may be omitted.

Referring to FIG. 2, the integrated circuit device la may include a pair of gate pillars PCPa extending along a first horizontal direction (X direction) and being spaced apart from each other in a second horizontal direction (Y direction) orthogonal to the first horizontal direction (X direction), and a plurality of gate groups PCG spaced apart from each other in a first horizontal direction (X direction) between a pair of gate pillars PCPa and disposed along a second horizontal direction (Y direction). The pair of gate pillars PCPa spaced apart from each other in the second horizontal direction (Y direction) may include a first gate pillar PCP1a and a second gate pillar PCP2a.

Each of the plurality of gate groups PCG may include a plurality of gate patterns PC disposed on a straight line extending in the second horizontal direction (Y direction) between the first gate pillar PCP1a and the second gate pillar PCP2a. A plurality of gate cut regions GC may be disposed between the first gate pillar PCP1a and the second gate pillar PCP2a. Dummy gate patterns DPC connected to the first gate pillar PCP1a may be first dummy gate patterns DPC1, and dummy gate patterns DPC connected to the second gate pillar PCP2a may be second dummy gate patterns DPC2.

At least one edge dummy pattern EDP may be spaced apart from each of the plurality of gate patterns PC. At least one edge dummy pattern EDP may contact and be connected to each of the pair of gate pillars PCPa. For example, one end of the first gate pillar PCP1a may be in contact with and connected to the first edge dummy pattern EDP1, and the other end of the first gate pillar PCP1a may be in contact with and connected to the second edge dummy pattern EDP2. For example, one end of the second gate pillar PCP2a may be in contact with and connected to the first edge dummy pattern EDP1, and the other end of the second gate pillar PCP2a may be in contact with and connected to the second edge dummy pattern EDP2. The first edge dummy pattern EDP1, the first gate pillar PCP1a, the second edge dummy pattern EDP2, and the second gate pillar PCP2a are sequentially connected to each other and surround the plurality of gate patterns PC. The plurality of gate patterns PC surrounded by the first edge dummy pattern EDP1, the first gate pillar PCP1a, the second edge dummy pattern EDP2, and the second gate pillar PCP2a may constitute one functional block IP. For example, the integrated circuit device la may include a plurality of functional blocks IP, and each functional block IP may be surrounded by a first edge dummy pattern EDP1, a first gate pillar PCP1a, a second edge dummy pattern EDP2, and a second gate pillar PCP2a. The first gate pillar PCP1a, the second gate pillar PCP2a, the first edge dummy pattern EDP1, and the second edge dummy pattern EDP2 may be integrally formed.

Among the plurality of gate cut regions GC disposed between the first gate pillar PCP1a and the second gate pillar PCP2a, gate cut regions GC adjacent to the first dummy gate patterns DPC1 and the second dummy gate patterns DPC2 may be referred to as dummy gate cut regions GCD. One ends of the first dummy gate patterns DPC1 may be connected to the first gate pillar PCP1a, and other ends of the first dummy gate patterns DPC1 may contact and be disconnected from the first dummy gate cut region GCD1. One ends of the second dummy gate patterns DPC2 may be connected to the second gate pillar PCP2a, and other ends of the second dummy gate patterns DPC2 may contact and be disconnected from the second dummy gate cut region GCD2.

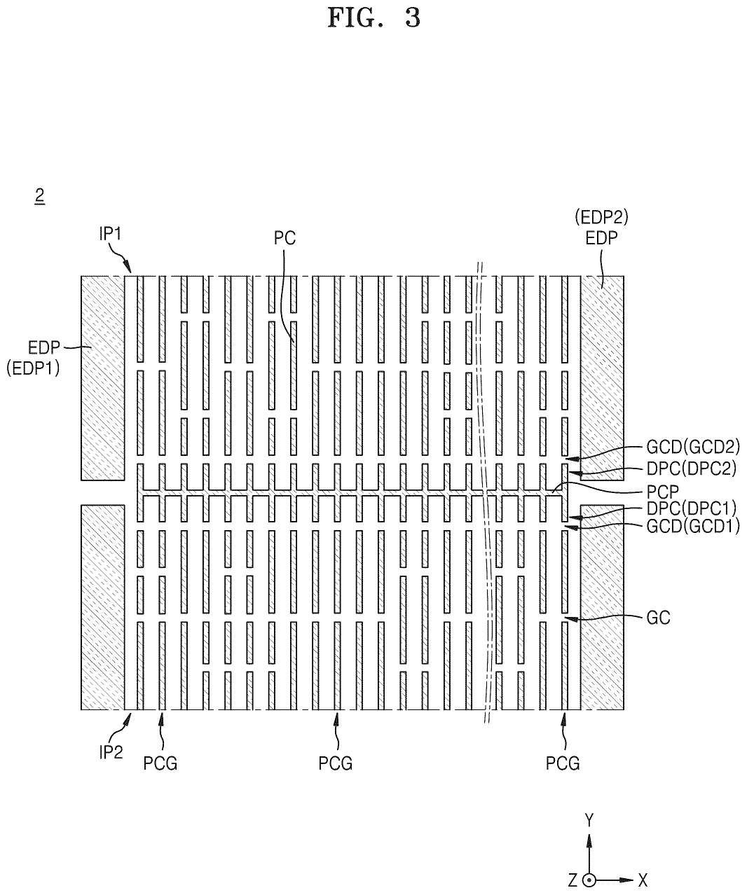

FIG. 3 is a plan layout view illustrating an integrated circuit device according to embodiments of inventive concepts. Among the contents of FIG. 3, descriptions overlapping those of FIGS. 1A to 1C may be omitted.

Referring to FIG. 3, the integrated circuit device 2 includes a plurality of functional blocks including a first functional block IP1 and a second functional block IP2 adjacent to each other. The first functional block IP1 and the second functional block IP2 may be disposed adjacent to each other in the second horizontal direction (Y direction). In some embodiments, each of the first functional block IP1 and the second functional block IP2 may have substantially the same width in the first horizontal direction (X direction).

A plurality of gate patterns PC constituting the first functional block IP1, and at least one edge dummy pattern EDP disposed on at least one side of the plurality of gate patterns PC constituting the first functional block IP1 in the first horizontal direction (X direction) are substantially the same as a plurality of gate patterns PC constituting the functional block IP included in the integrated circuit device 1 shown in FIGS. 1A to 1C, and at least one edge dummy pattern EDP disposed on at least one side of a plurality of gate patterns PC constituting a functional block IP in a first horizontal direction (X direction), and a plurality of gate patterns PC constituting the second functional block IP2, and at least one edge dummy pattern EDP disposed on at least one side of the plurality of gate patterns PC constituting the second functional block IP2 in the first horizontal direction (X direction) are substantially the same as a plurality of gate patterns PC constituting the functional block IP included in the integrated circuit device 1 shown in FIGS. 1A to 1C, and thus, a detailed description is omitted, and if necessary, description is given with reference to FIGS. 1A to 1C.

At least one edge dummy pattern EDP disposed on at least one side of the plurality of gate patterns PC constituting the first functional block IP1 and at least one edge dummy pattern EDP disposed on at least one side of the plurality of gate patterns PC constituting the second functional block IP2 may be aligned with each other in the second horizontal direction (Y direction) and may be spaced apart from each other in the second horizontal direction (Y direction).

The second dummy gate patterns DCP2 (hereinafter referred to as second dummy gate patterns DCP2 of the first functional block IP1) among the plurality of gate patterns PC constituting the first functional block IP1 (hereinafter, the plurality of gate patterns PC of the first functional block IP1 and the first dummy gate patterns DCP1 (hereinafter, the first dummy gate patterns DCP1 of the second functional block IP2) among the plurality of gate patterns PC constituting the second functional block IP2 (hereinafter, the plurality of gate patterns PC of the second functional block IP2) may be adjacent to each other. The gate pillar PCP disposed between the second dummy gate patterns DCP2 of the first functional block IP1 and the first dummy gate patterns DCP1 of the second functional block IP2 may be connected in contact with the second dummy gate patterns DCP2 of the first functional block IP1 and may also be connected in contact with the first dummy gate patterns DCP1 of the second functional block IP2. The second dummy gate patterns DCP2 of the first functional block IP1, the first dummy gate patterns DCP1 of the second functional block IP2, and the gate pillar PCP connected to each other may be integrally formed.

The gate pillar PCP disposed between the second dummy gate patterns DCP2 of the first functional block IP1 and the first dummy gate patterns DCP1 of the second functional block IP2 may be a common gate pillar that combines the function of the second gate pillar PCP2 (see FIG. 1) surrounding the first functional block IP1 and the function of the first gate pillar PCP1 (see FIG. 1) surrounding the second functional block IP2. It is apparent to those skilled in the art that the integrated circuit device 2 includes a first gate pillar PCP1 (see FIG. 1) surrounding the first functional block IP1 and a second gate pillar PCP2 (see FIG. 1) surrounding the second functional block IP2, and the first gate pillar PCP1 (see FIG. 1) surrounding the first functional block IP1, the gate pillar PCP shown in FIG. 3, which is a common gate pillar line surrounding the first functional block IP1 and the second functional block IP2, and the second gate pillars PCP2 (see FIG. 1) surrounding the second functional block IP2 may be referred to as a first gate pillar, a second gate pillar, and a third gate pillar, respectively.

In relation to the integrated circuit device 2 according to embodiments of inventive concepts, by the gate pillar PCP disposed between the second dummy gate patterns DCP2 of the first functional block IP1 and the first dummy gate patterns DCP1 of the second functional block IP2, in the second horizontal direction (Y direction), the first functional block IP1 and the second functional block IP2 are adjacent to each other as much as possible, for example, as much as the width of the gate pillar PCP (the second width W2 in FIG. 1B). Therefore, the space between the plurality of functional blocks included in the integrated circuit device 2 may be limited and/or minimized, so that the size, that is, the area, of the integrated circuit device 2 may be reduced without reducing the degree of integration of the integrated circuit device 2.

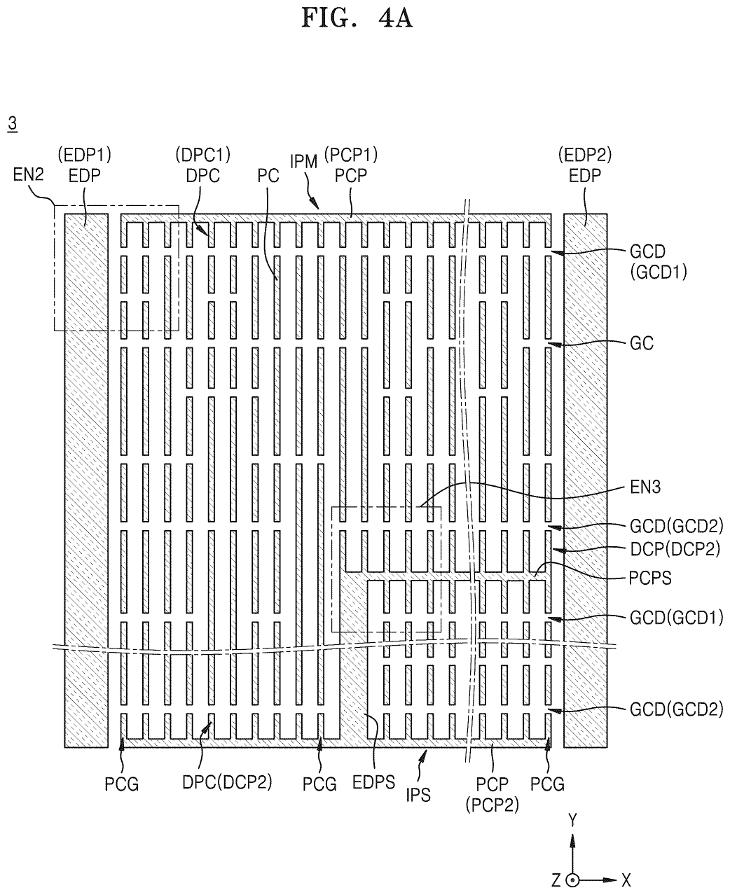

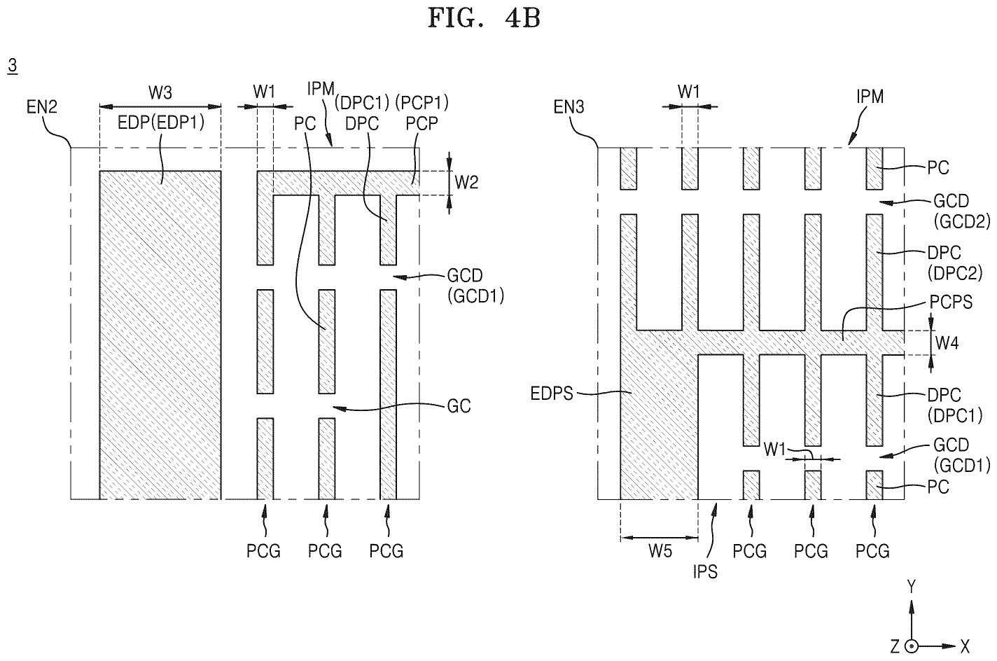

FIGS. 4A and 4B are planar arrangement views and partially enlarged views illustrating an integrated circuit device according to embodiments of inventive concepts. FIG. 4B is an enlarged plan view illustrating portions EN2 and EN3 of FIG. 4A. Among the contents of FIG. 3, descriptions overlapping those of FIGS. 1A to 3 may be omitted.

Referring to FIG. 4A, the integrated circuit device 3 includes a plurality of functional blocks including a main functional block IPM and a sub-functional block IPS adjacent to each other. The main functional block IPM may have a greater area than the sub-functional block IPS. The main functional block IPM may be referred to as a first functional block, and the sub-functional block IPS may be referred to as a second functional block. In some embodiments, the sub-functional block IPS may have a rectangular shape in plan view, and both the main functional block IPM and the sub-functional block IPS may have a rectangular shape in plan view. The sub-functional block IPS may be disposed such that at least two sides of the four sides of the sub-functional block IPS are adjacent to the main functional block IPM. For example, one of the four sides of the sub-functional block (IPS) may be adjacent to the main functional block (IPM) in a first horizontal direction (X direction), and another side may be adjacent to the main functional block (IPM) in a second horizontal direction (Y direction).

A plurality of gate patterns PC constituting each of the main functional block IPM and the sub-functional block IPS, and at least one edge dummy pattern EDP in which a main functional block IPM and a sub-functional block IPS having a rectangular shape in plan are disposed on one side of the at least one edge dummy pattern EDP are substantially the same as a plurality of gate patterns PC constituting the functional block IP included in the integrated circuit device 1 shown in FIG. 1, and at least one edge dummy pattern EDP disposed on at least one side of the plurality of gate patterns PC constituting the functional block IP in a first horizontal direction (X direction), respectively, and thus, a detailed description is omitted, and if necessary, description is given with reference to FIG. 1.

Some of the second dummy gate patterns DCP2 (hereinafter referred to as second dummy gate patterns DCP2 of the main functional block IPM) among the plurality of gate patterns PC constituting the main functional block IPM (hereinafter, the plurality of gate patterns PC of the main functional block IPM) and the first dummy gate patterns DCP1 (hereinafter, the first dummy gate patterns DCP1 of the sub-functional block IPS) among the plurality of gate patterns PC constituting the sub-functional block IPS (hereinafter, the plurality of gate patterns PC of the sub-functional block IPS) may be adjacent to each other. A sub-gate pillar PCPS may be disposed between some of the second dummy gate patterns DCP2 of the main functional block IPM and the first dummy gate patterns DCP1 of the sub-functional block IPS. The sub-gate pillar PCPS may be in contact with and connected to some of the second dummy gate patterns DCP2 of the main functional block IPM, and may be in contact with and connected to the first dummy gate patterns DCP1 of the sub-functional block IPS. Some of the second dummy gate patterns DCP2 of the main functional block IPM connected to each other; the first dummy gate patterns DCP1 of the sub-functional block IPS, and the sub-gate pillar PCPS may be integrally formed. Another part of the second dummy gate patterns DCP2 of the main functional block IPM may be connected to and in contact with the second gate pillar PCP2.

The sub-gate pillar PCPS disposed between some of the second dummy gate patterns DCP2 of the main functional block (IPM) and the first dummy gate patterns DCP1 of the sub-functional block IPS may be a common gate pillar that combines the function of the second gate pillar PCP2 (see FIG. 1) surrounding the main functional block IPM and the function of the first gate pillar PCP1 (see FIG. 1) surrounding the sub-functional block IPS.

A sub-edge dummy pattern EDPS may be disposed between a main functional block IPM and a sub-functional block IPS adjacent in a first horizontal direction (X direction). The sub-edge dummy pattern EDPS may be a common gate pillar that combines the function of the second edge dummy pattern EDP2 (see FIG. 1) surrounding the main functional block IPM and the function of the first edge dummy pattern EDP2 (see FIG. 1) surrounding the sub-functional block IPS.

The first dummy gate patterns DPC1 including the plurality of gate patterns PC of the main functional block IPM and contacting and connected to the first gate pillar PCP1 may all have the same extension length in the second horizontal direction (Y direction). The first dummy gate patterns DPC1 including the plurality of gate patterns PC of the main functional block IPM and contacting and connected to the first gate pillar PCP1 may all have the same extension length in the second horizontal direction (Y direction). Some of the second dummy gate patterns DCP2 of the main functional block IPM including the plurality of gate patterns PC of the main functional block IPM and contacting and connected to the second gate pillar PCP2 may all have the same extension length in the second horizontal direction (Y direction).

The first dummy gate patterns DPC1 including the plurality of gate patterns PC of the main functional block IPM and contacting and connected to the first gate pillar PCP1 may all have the same extension length in the second horizontal direction (Y direction). The second dummy gate patterns DPC2 included in the plurality of gate patterns PC of the sub-functional block IPS may be connected to the second gate pillar PCP2 and may have the same extension length in the second horizontal direction (Y direction).

Referring to FIGS. 4A and 4B together, the sub-gate pillar PCPS may have a fourth width W4 in the second horizontal direction (Y direction). The fourth width W4 may have a greater value than the first width W1. In some embodiments, the fourth width W4 may be substantially equal to the second width W2. The sub-edge dummy pattern EDPS may have a fifth width W5 in the first horizontal direction (X direction). The fifth width W5 may have a greater value than each of the first width W1, the second width W2, and the fourth width W4. The fifth width W5 may have a value equal to or less than the third width W3. In some embodiments, the fifth width W5 may have a value at least three times greater than the first width W1. In some embodiments, the fifth width W5 may be equal to the sum of the distance between two adjacent second dummy gate patterns DCP2 of the main functional block IPM in the first horizontal direction (X direction) and twice the first width W1.

In some embodiments, the sub-edge dummy pattern EDPS may contact and be connected to each of the sub-gate pillar PCPS and the second gate pillar PCP2. For example, the second gate pillar PCP2, the sub-edge dummy pattern EDPS, the plurality of second dummy gate patterns DPC2 of the main functional block IPM, the plurality of first dummy gate patterns DPC1 of the sub-functional block IPS, and the plurality of second dummy gate patterns DPC2 of the sub-functional block IPS may be integrally formed.

In the integrated circuit device 3 according to embodiments of inventive concepts, a main functional block IPM and a sub-functional block IPS may be arranged as close to each other as possible by the sub-gate pillar PCPS and the sub-edge dummy pattern EDPS. For example, the main functional block IPM and the sub-functional block IPS may be disposed adjacent to each other by the fourth width W4 of the sub-gate pillar PCP in the second horizontal direction (Y direction) and may be disposed adjacent to each other by a fifth width W5 of the sub-edge dummy pattern EDPS in the first horizontal direction (X direction).

Therefore, the space between the plurality of functional blocks included in the integrated circuit device 3 may be limited and/or minimized, so that the size, that is, the area, of the integrated circuit device 3 may be reduced without reducing the degree of integration of the integrated circuit device 3.

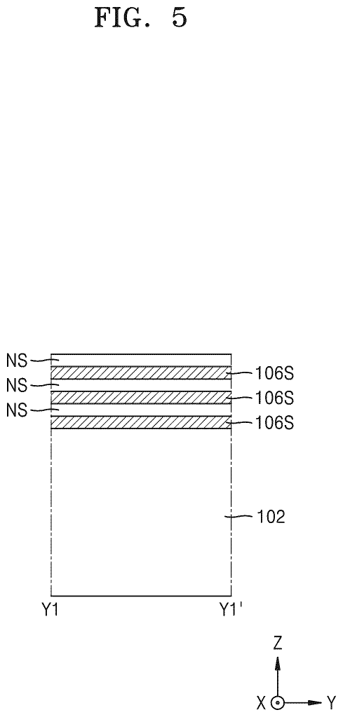

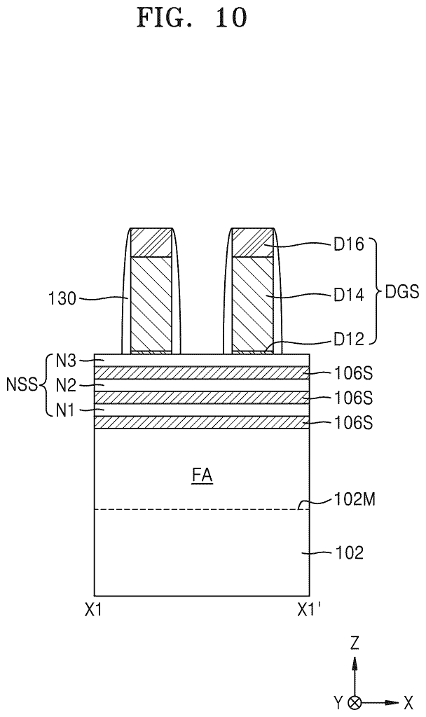

FIGS. 5 to 15 are cross-sectional views for explaining a manufacturing method of an integrated circuit device according to embodiments of inventive concepts. FIGS. 5, 6, 7, 8, and 9 are cross-sectional views taken along portions corresponding to lines Y1-Y1′ in FIG. 1A, and FIGS. 10, 11, 12, 13, 14, and 15 are cross-sectional views taken along portions corresponding to lines X1-X1′.

Referring to FIG. 5, a plurality of sacrificial semiconductor layers 106S and a plurality of nanosheet semiconductor layers NS are alternately stacked one by one on a substrate 102. The plurality of sacrificial semiconductor layers 106S and the plurality of nanosheet semiconductor layers NS may be made of different materials. For example, the plurality of sacrificial semiconductor layers 106S and the plurality of nanosheet semiconductor layers NS may be made of different semiconductor materials. In some embodiments, the plurality of nanosheet semiconductor layers NS may include a semiconductor material made of a single element, and the plurality of sacrificial semiconductor layers 106S may include a compound semiconductor material. For example, the plurality of nanosheet semiconductor layers NS may be made of the same material as that of the substrate 102. In some embodiments, the plurality of sacrificial semiconductor layers 106S may be made of SiGe, and the plurality of nanosheet semiconductor layers NS may be made of Si, but the examples are not limited thereto.

The plurality of sacrificial semiconductor layers 106S may all be formed to have the same thickness, but the technical idea of inventive concepts is not limited thereto. In some embodiments, the thickness of the sacrificial semiconductor layer 106S closest to the substrate 102 among the plurality of sacrificial semiconductor layers 106S may be greater than the thickness of the remaining sacrificial semiconductor layers 106S.

The substrate 102 may include a semiconductor material, such as Si or Ge, or a compound semiconductor material, such as SiGe, SiC, GaAs, InAs, or InP. In some embodiments, the substrate 102 may be made of at least one of a group III-V material and a group IV material. The group III-V material may be a binary, ternary, or quaternary compound semiconductor material including at least one group III element and at least one group V element. In some embodiments, when forming an NMOS transistor on a portion of the substrate 102, the portion of the substrate 102 may be made of any of the III-V materials illustrated above. In some other embodiments, when forming a PMOS transistor on a portion of the substrate 102, the portion of the substrate 102 may include Ge. In another example, the substrate 102 may have a semiconductor on insulator (SOI) structure. The substrate 102 may include a conductive region, for example, a well doped with an impurity, or a structure doped with an impurity.

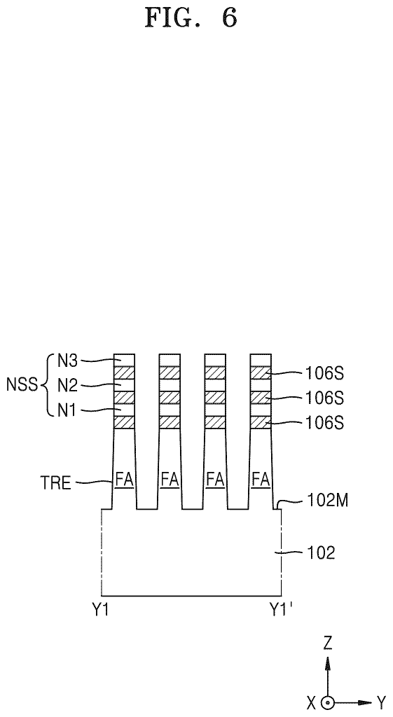

Referring to FIG. 6, a plurality of trenches TRE are formed by etching a portion of the stacked structure of the plurality of sacrificial semiconductor layers 106S and the plurality of nanosheet semiconductor layers NS and a portion of the substrate 102. As a result, a plurality of fin-type active regions FA defined by the plurality of trenches TRE may be formed. The plurality of fin-type active regions F1 and F2 may extend parallel to each other along a first horizontal direction (X direction). A plurality of fin-type active regions FA may protrude upward from the main surface 102M of the substrate 102 in a vertical direction (Z direction). The main surface 102M of the substrate 102 may be a bottom surface of a plurality of trenches TRE. A plurality of fin-type active regions FA may be arranged at a constant pitch in the second horizontal direction (Y direction). The plurality of fin-type active regions FA refers to portions of the substrate 102 defined by the plurality of trenches TRE.

A stacked structure NSS of a plurality of sacrificial semiconductor layers 106S and a plurality of nanosheets N1, N2, and N3 may be disposed on the plurality of fin-type active regions FA. The stacked structure NSS of the plurality of nanosheets N1, N2, and N3 may be formed by removing a portion of the plurality of nano sheet semiconductor layers NS by etching. In this example, a stacked structure NSS of a plurality of nanosheets N1, N2, and N3 including three nanosheets N1, N2, N3, for example, a case including the first nanosheet N1, the second nanosheet N2, and the third nanosheet N3 has been exemplified, but the technical idea of inventive concepts is not limited to the example.

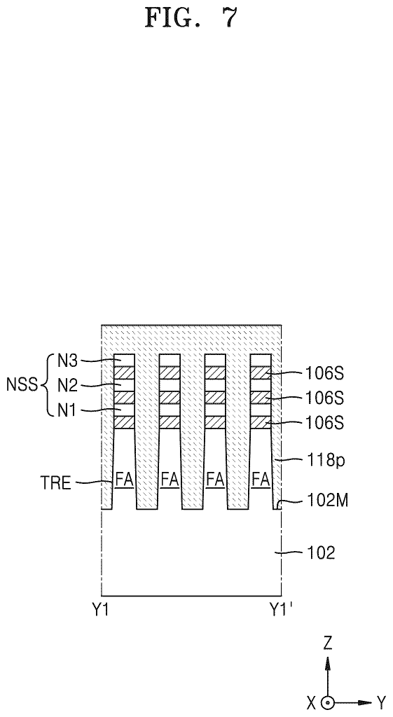

Referring to FIG. 7, a preliminary element isolation film 118p filling the plurality of trenches TRE is formed. The preliminary element isolation film 118p may be formed to cover sidewalls of the plurality of fin-type active regions FA and sidewalls and upper surfaces of a stacked structure NSS of the plurality of nanosheets N1, N2, and N3. The preliminary element isolation film 118p may be made of a material including at least one of, for example, silicon oxide, silicon nitride, and silicon oxynitride. The preliminary element isolation film 118p may be composed of a single layer made of one kind of insulating film, a double layer made of two kinds of insulating film, or a multi-layer made of a combination of at least three kinds of insulating films. For example, the preliminary element isolation film 118p may be formed of two different types of insulating films. For example, the preliminary element isolation film 118p may be formed of a silicon oxide film and a silicon nitride film. For example, the preliminary element isolation film 118p may be formed of a triple layer including a silicon oxide film, a silicon nitride film, and a silicon oxide film.

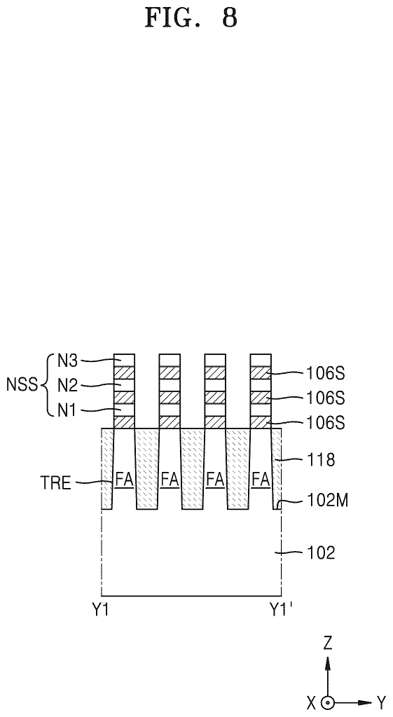

Referring to FIGS. 7 and 8 together, the element isolation film 118 is formed by performing a recess process for removing a partial thickness of the preliminary element isolation film 118p from the top thereof. To perform the recess process, dry etching, wet etching, or a combination of dry and wet etching processes may be used. The element isolation film 118 may be made of a material including at least one of, for example, silicon oxide, silicon nitride, and silicon oxynitride. The element isolation film 118 may be composed of a single layer made of one kind of insulating film, a double layer made of two kinds of insulating film, or a multi-layer made of a combination of at least three kinds of insulating films.

The recess process may be performed so that the upper surface of the element isolation film 118 is at the same or substantially similar level as the upper surface 104 of the fin-type active region FA. As a result, the stacked structure NSS of the plurality of nanosheets N1, N2, and N3 on the plurality of fin-type active regions FA and the sidewalls of the plurality of sacrificial semiconductor layers 106S may be exposed.

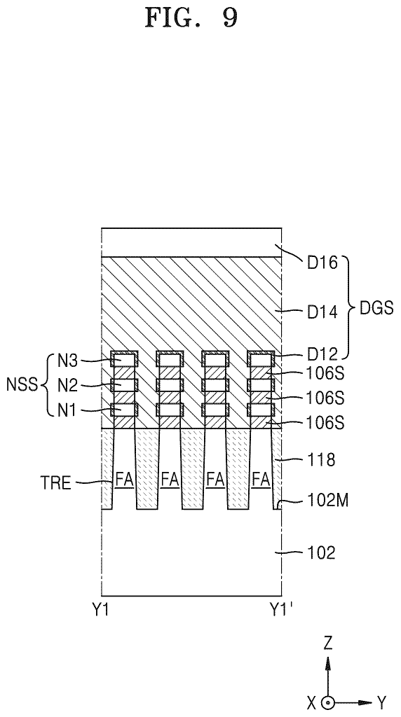

Referring to FIGS. 9 and 10 together, a plurality of dummy gate structures DGS extending to cross at least a portion of the plurality of fin-type active regions FA are formed on a plurality of fin-type active regions FA in which a stacked structure NSS of a plurality of nanosheets N1, N2, and N3 is formed. The plurality of dummy gate structures DGS may extend parallel to each other in the second horizontal direction (Y direction).

The dummy gate structure DGS may have a structure in which an oxide film D12, a dummy gate layer D14, and a capping layer D16 are sequentially stacked. In one example for forming the dummy gate structure DGS, to cover the exposed surfaces of a stacked structure NSS of a plurality of nanosheets N1, N2, and N3 covering a plurality of fin-type active regions FA, the exposed surfaces of the plurality of sacrificial semiconductor layers 106S, the exposed surfaces of a plurality of finned active regions FA, and the upper surface of the element isolation film 118, respectively, after sequentially forming a preliminary oxide film, a preliminary dummy gate layer, and a preliminary capping layer, the oxide film D12, the dummy gate layer D14, and the capping layer D16 may be formed by patterning the preliminary oxide film, the preliminary dummy gate layer, and the preliminary capping layer. The dummy gate structure DGS may be formed through an extreme ultraviolet lithography (EUV) process. For example, the dummy gate structure DGS may be formed by patterning the preliminary oxide film, the preliminary dummy gate layer, and the preliminary capping layer through an EUV lithography process.

In some embodiments, the dummy gate layer D14 may be made of polysilicon, and the capping layer D16 may be made of silicon nitride, but inventive concepts is not limited thereto.

Thereafter, a plurality of gate spacers 130 are formed to cover both sidewalls of the plurality of dummy gate structures DGS. A pair of gate spacers 130 among the plurality of gate spacers 130 may cover both sidewalls of each of the plurality of dummy gate structures DGS. To form a plurality of gate spacers 130, after forming a spacer layer on the semiconductor substrate 102 on which the dummy gate structure DGS is formed, the spacer layer may be etched back to form a plurality of gate spacers 130 that are portions of the spacer layer covering both sidewalls of the plurality of dummy gate structures DGS. The gate spacer 130 may be made of, for example, silicon nitride.

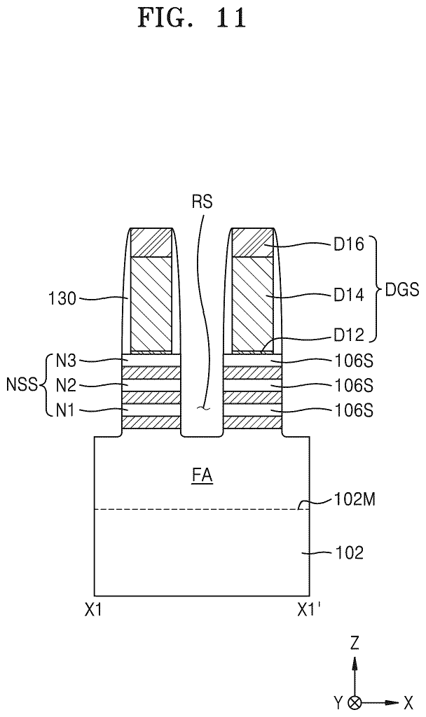

Referring to FIGS. 10 and 11 together, the plurality of dummy gate structures DGS and the plurality of gate spacers 130 are used as etch masks so that a plurality of recess regions RS are formed by removing portions of the stacked structure NSS of the plurality of nanosheets N1, N2, and N3 and portions of the plurality of sacrificial semiconductor layers 106S by etching. Fin-type active regions FA may be exposed on bottom surfaces of the plurality of recess regions RS. In some embodiments, in the process of etching portions of the stacked structure NSS of the plurality of nanosheets N1, N2, and N3 and portions of the plurality of sacrificial semiconductor layers 106S, upper portions of the fin-type active region FA may be removed together. For example, bottom surfaces of the plurality of recess regions RS may be located at a vertical level lower than the top of the fin-type active region FA.

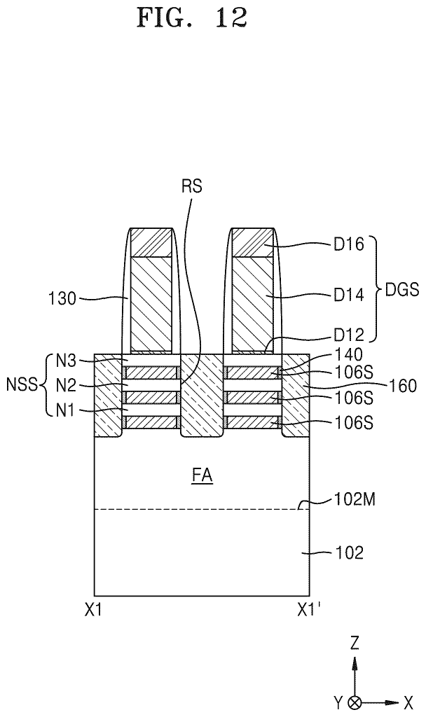

Referring to FIGS. 11 and 12 together, after removing portions of the plurality of sacrificial semiconductor layers 106S exposed from both sides of each of the plurality of nanosheet stacked structures NSS using an isotropic etching process to form removal spaces, a plurality of insulating spacers 140 filling the removal spaces formed between the plurality of nanosheets N1, N2, and N3, respectively, are formed. The plurality of insulating spacers 140 may be made of, for example, silicon nitride. In some embodiments, the plurality of insulating spacers 140 may be formed by stacking a plurality of insulating layers.

After forming a plurality of insulating spacers 140, a plurality of source/drain regions 160 are formed by epitaxially growing a semiconductor material from the exposed sidewalls of the plurality of nanosheets N1, N2, and N3 and the exposed surfaces of the plurality of fin-type active regions FA.

In some embodiments, some and other portions of the plurality of source/drain regions 160 may include different materials, and some of the plurality of source/drain regions 160 including different materials may be formed by performing separate epitaxial growth processes. For example, some of the plurality of source/drain regions 160 may include Ge. In some embodiments, some of the plurality of source/drain regions 160 may have a multilayer structure of a semiconductor material including Si and a semiconductor material including Ge.

For example, other portions of the plurality of source/drain regions 160 may include Si but not Ge. In some embodiments, other portions of the plurality of source/drain regions 160 may be made of a multilayer structure of a semiconductor material including Si, and a semiconductor material such as Si or a compound semiconductor material such as SiC.

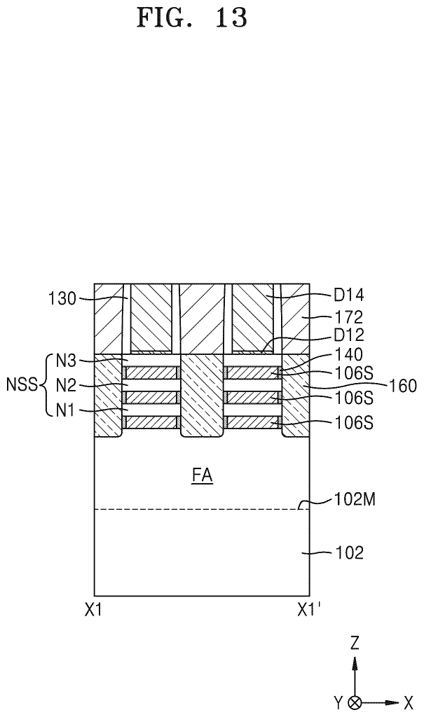

Referring to FIGS. 12 and 13 together, after forming the inter-gate insulating film 172 on the plurality of dummy gate structures DGS and the plurality of source/drain regions 160, the inter-gate insulating layer 172 is planarized to remove the plurality of capping layers D16 covering the upper surfaces of the plurality of dummy gate layers D14, and the plurality of gate spacers 130 and the inter-gate insulating film 172 around the plurality of capping layers D16 are polished from the top to a partial thickness, so that the upper surface of the inter-gate insulating layer 172 and the upper surface of the plurality of dummy gate layers D14 may be positioned at substantially the same level to form a coplanar surface. In some embodiments, the inter-gate insulating film 172 may be formed of silicon oxide or an insulating material having a lower dielectric constant than silicon oxide. In some embodiments, the inter-gate insulating film 172 may be formed of an ultra low k (ULK) film having an ultra low dielectric constant K of about 2.2 to about 2.4. The ULK film may include a SiOC film or a SiCOH film.

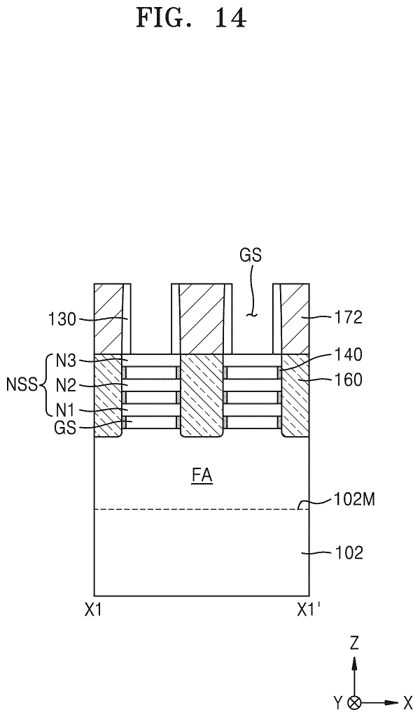

Referring to FIGS. 13 and 14 together, after removing the plurality of dummy gate layers D14 exposed through the inter-gate insulating film 172 and the gate spacer 130 and the plurality of oxide films D12 thereunder, at least a portion of the plurality of sacrificial semiconductor layers 106S remaining on the fin-type active region FA is removed to form a plurality of gate spaces GS. Surfaces of the plurality of nanosheets N1, N2, and N3 and portions of upper surfaces of the plurality of fin-type active regions FA may be exposed through the gate space GS. In some embodiments, a portion of the plurality of sacrificial semiconductor layers 106S may remain without being removed.

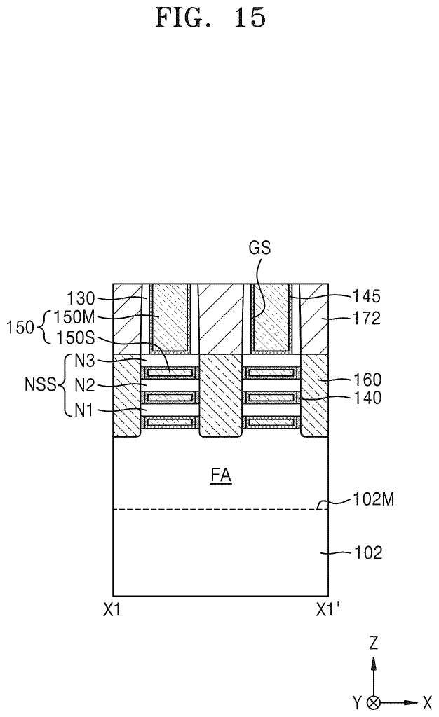

Referring to FIGS. 14 and 15 together, a gate dielectric film 145 is formed on surfaces exposed in the plurality of gate spaces GS, for example, surfaces of the plurality of nanosheets N1, N2, and N3, and upper surfaces of the plurality of fin-type active regions FA, and a plurality of gate electrode layers 150 filling the plurality of gate spaces GS are formed on the gate dielectric film 145. The plurality of gate electrode layers 150 may extend parallel to each other in the second horizontal direction (Y direction). After forming a gate material layer filling the plurality of gate spaces GS on the gate dielectric film 145, an upper part of the gate material layer is removed until the inter-gate insulating film 172 and the gate spacer 130 are exposed, so that a plurality of gate electrode layers 150 may be formed. In some embodiments, the plurality of gate electrode layers 150 may be formed by removing an upper portion of the gate material layer by performing a planarization process such as a CMP process. For example, the upper surface of each of the plurality of gate electrode layers 150 may be positioned at the same vertical level.

The gate dielectric film 145 may include a stacked structure of an interface layer and a high dielectric film. In some embodiments, the interface film may be formed of a low-k material layer having a dielectric constant of about 9 or less, for example, silicon oxide, silicon oxynitride, or a combination thereof. In some embodiments, the interface film may be omitted. The high dielectric film may be made of a material having a higher dielectric constant than silicon oxide. For example, the high dielectric film may have a dielectric constant of about 10 to about 25.

The gate electrode layer 150 may include a metal-containing layer for adjusting the work function and a metal-containing layer for filling a gap filling a space above the metal-containing layer for adjusting the work function. In some embodiments, the gate electrode layer 150 may have a structure in which a metal nitride layer, a metal layer, a conductive capping layer, and a gap-fill metal layer are sequentially stacked.

The gate electrode layer 150 may include a main gate portion 150M covering an upper surface of a nanosheet stacked structure NSS including a plurality of nanosheets N1, N2, and N3, a space connected to the main gate portion 150M and between each of the plurality of nanosheets N1, N2, and N3, and a plurality of sub-gate portions 150S formed in the space between the first nanosheet N1, which is the lowest nanosheet among the plurality of nanosheets N1, N2, and N3, and the fin-type active region FA.

A plurality of insulating spacers 140 may be disposed on both ends of each of the plurality of sub-gate portions 150S with the gate dielectric film 145 disposed therebetween.

FIGS. 16A to 16E are cross-sectional views illustrating an integrated circuit device according to embodiments of inventive concepts. FIG. 16A is a cross-sectional view taken along line Y1-Y1′ in FIG. 1A, FIG. 16B is a cross-sectional view taken along line X1-X1′ in FIG. 1A, FIG. 16C is a cross-sectional view taken along line X1-X1′ of FIG. 1A, FIG. 16C is a cross-sectional view taken along line Y2-Y2′ of FIG. 1A, FIG. 16D is a cross-sectional view taken along the line X2-X2′ of FIG. 1A, and FIG. 16E is a cross-sectional view taken along the line Y3-Y3′ of FIG. 1A.

Referring to FIG. 1A and FIGS. 16A to 16E, a plurality of gate cut regions GC including dummy gate cut regions GCD are formed by removing portions of the plurality of gate electrode layers 150, and an interlayer insulating film 174 covering the plurality of gate electrode layers 150 and the insulating film 172 between the gates is formed. In some embodiments, an interlayer insulating film 174 may be filled in the plurality of gate cut regions GC. In some other embodiments, after forming another insulating material layer filling the plurality of gate cut regions GC before forming the interlayer insulating film 174, an interlayer insulating film 174 may be formed to cover the insulating material layer, the plurality of gate electrode layers 150 and the inter-gate insulating film 172.

Thereafter, portions of the interlayer insulating film 174 and portions of the inter-gate insulating film 172 are etched to form a plurality of first contact holes 192H exposing a plurality of source/drain regions 160, and a metal silicide layer 162 is formed on upper surfaces of each of the plurality of source/drain regions 160 exposed through the plurality of first contact holes 192H. In addition, portions of the interlayer insulating film 174 are etched to form a plurality of second contact holes 194H exposing upper surfaces of the plurality of gate electrode layers 150, that is, upper surfaces of the main gate portion 150M. In some embodiments, the plurality of first contact holes 192H and the plurality of second contact holes 194H may be formed together by a single etching process, but inventive concepts is not limited thereto, and each of the plurality of first contact holes 192H and the plurality of second contact holes 194H may be formed by a separate etching process.

Thereafter, a plurality of first contact plugs 192 filling the plurality of first contact holes 192H and a plurality of second contact plugs 194 filling the plurality of second contact holes 194H are formed to form an integrated circuit device 1.

The plurality of first contact plugs 192 may be connected to the plurality of source/drain regions 160 through the metal silicide film 162, and the plurality of second contact plugs 194 may be connected to the plurality of gate electrode layers 150. In some embodiments, the plurality of first contact plugs 192 and the plurality of second contact plugs 194 may be formed together, but inventive concepts is not limited thereto, and the plurality of first contact plugs 192 and the plurality of second contact plugs 194 may be formed by separate processes.

The integrated circuit device 1 may include a multi-gate MOSFET including a plurality of fin-type active regions FA protruding upward from the main surface 102M of the substrate 102 in a vertical direction (Z direction) and extending in a first horizontal direction (X direction), and a plurality of nanosheet stacked structures NSS facing the upper surface of each of the plurality of fin-type active regions FA at a position spaced apart in the vertical direction (Z direction) from the upper surface of each of the plurality of fin-type active regions FA.

A plurality of trenches TRE defining a plurality of fin-type active regions FA may be formed in the substrate 102. Sidewalls of the plurality of fin-type active regions FA may be covered with an element isolation film 118 filling the plurality of trenches TRE. The level of the upper surface of the plurality of fin-type active regions FA and the level of the upper surface of the element isolation film 118 may be the same or similar to each other.

A plurality of nanosheet stacked structures NSS are spaced apart from the upper surface of the fin-type active region FA in a vertical direction (Z direction). The plurality of nano sheet stacked structure NSS may include a plurality of nanosheets N1, N2, and N3 extending in parallel with the upper surface of each of the plurality of fin-type active regions FA on the substrate 102.

A plurality of nanosheets N1, N2, and N3 constituting one nanosheet stacked structure NSS are stacked one by one on the upper surface of each of the plurality of fin-type active regions FA. Each of the plurality of nanosheets N1, N2, and N3 may have a channel region. For example, the plurality of nanosheets N1, N2, and N3 may be made of a single material. In some embodiments, the plurality of nanosheets N1, N2, and N3 may be made of the same material as that of the substrate 102 in the cell region CR.

A plurality of gate electrode layers 150 may be disposed on the plurality of fin-type active regions FA. At least some of the plurality of gate electrode layers 150 may extend in a second horizontal direction (Y direction) crossing the first horizontal direction (X direction). At least a portion of the plurality of gate electrode layers 150 may overlap each of the plurality of nanosheet stacked structures NSS in a vertical direction (Z direction).

Each of the plurality of gate electrode layers 150 may be formed to surround at least a portion of the plurality of nanosheets N1, N2, and N3 while covering the nanosheet stacked structure NSS. The gate electrode layer 150 may include a main gate portion 150M covering the upper surface of the nanosheet stacked structure NSS, and a plurality of sub-gate portions 150S connected to the main gate part 150M and formed in the space between the fin-type active region FA and the plurality of nanosheets N1, N2, and N3, that is, on the lower side of each of the plurality of nanosheets N1, N2, and N3. A gate dielectric film 145 is formed between the nanosheet stacked structure NSS and the gate electrode layer 150.

A plurality of source/drain regions 160 are formed on the plurality of fin-type active regions FA. The plurality of source/drain regions 160 are connected to ends of the plurality of neighboring nanosheets N1, N2, and N3, respectively.

A gate spacer 130 sequentially covering sidewalls of the gate electrode layer 150 is formed on the plurality of nanosheet stacked structures NSS. The gate spacer 130 may be formed of a silicon nitride film, but is not limited thereto. The gate spacer 130 may cover sidewalls of the main gate portion 150M of the gate electrode layer 150.

An insulating spacer 140 in contact with the source/drain region 160 is formed in a space between each of the plurality of nanosheets N1, N2, and N3. The insulating spacer 140 may be disposed between the sub-gate portion 150S and the source/drain region 160 in the space between the fin-type active region FA and each of the plurality of nanosheets N1, N2, and N3.

An inter-gate insulating film 172 and an interlayer insulating film 174 are sequentially formed on the plurality of source/drain regions 160. The inter-gate insulating film 172 and the interlayer insulating film 174 may each be made of silicon oxide or an insulating material having a lower dielectric constant than silicon oxide, but are not limited thereto.

A plurality of first contact plugs 192 may be connected to the plurality of source/drain regions 160. The first contact plug 192 may pass through the interlayer insulating film 174 and the inter-gate insulating film 172 and be connected to the source/drain region 160. The metal silicide film 162 may be disposed between the source/drain region 160 and the first contact plug 192. In some embodiments, the metal silicide film 162 may be omitted.

A plurality of second contact plugs 194 may be connected to the plurality of gate electrode layers 150. The second contact plug 194 may pass through the interlayer insulating film 174 and be connected to the gate electrode layer 150.

Each of the first contact plug 192 and the second contact plug 194 may be made of metal, conductive metal nitride, or a combination thereof.

The plurality of gate electrode layers 150 may be the plurality of gate patterns PC shown in FIGS. 1A to 1C. The plurality of gate patterns PC are spaced apart from each other in the first horizontal direction (X direction) and extend in the second horizontal direction (Y direction), and some of the plurality of gate electrode layers 150 may be circuit gate patterns RPC. The circuit gate pattern RPC may cross the pin-type active region FA and be connected to the second contact plug 194.

Other some of the plurality of gate electrode layers 150 may be dummy gate patterns DPCs shown in FIGS. 1A to 1C. The plurality of gate patterns PC including circuit gate patterns RPC and dummy gate patterns DPC may have a first width W1 in a first horizontal direction (X direction).

Other some of the plurality of gate electrode layers 150 may be gate pillars PCP shown in FIGS. 1A to 1C. The gate pillars PCP may be disposed on the substrate 102 with the gate dielectric film 145 therebetween. The gate pillars PCP may extend in the first horizontal direction (X direction). In some embodiments, the gate pillars PCP may have a second width W2 greater than the first width W1 in the first horizontal direction (X direction).

Other some of the plurality of gate electrode layers 150 may be at least one edge dummy pattern EDP shown in FIGS. 1A to 1C. A cross section of the X-Z plane or the Y-Z plane of the at least one edge dummy pattern EDP may be substantially the same as that of the gate pillar PCP shown in FIG. 16C except for an extension direction/length and a horizontal width.

Each of the plurality of gate patterns PC including the circuit gate patterns RPC and the dummy gate patterns DPC, the gate pillars PCP, and the at least one edge dummy pattern EDP is any one of a plurality of gate electrode layers 150, and since the upper surface of each of the plurality of gate electrode layers 150 may be positioned at the same vertical level, upper surfaces of each of the plurality of gate patterns PC including the circuit gate patterns RPC and the dummy gate patterns DPC, the gate pillars PCP, and at least one edge dummy pattern EDP may be located on the same vertical level.

A gate cut region GC may be defined between two gate patterns PC adjacent to each other in the second horizontal direction (Y direction). Dummy gate cut regions GCD including a first dummy gate cut region GCD1 and a second dummy gate cut region GCD2 may be defined between the first dummy gate patterns DPC1 and the gate patterns PC adjacent to the first dummy gate patterns DPC1 in the second horizontal direction (Y direction) and between the second dummy gate patterns DPC2 between the gate patterns PC adjacent to the first dummy gate patterns DPC1 in the second horizontal direction (Y direction).

Referring to FIGS. 1A to 16E together, in relation to the integrated circuit device 1 according to embodiments of inventive concepts, since a plurality of dummy gate structures DGS including portions corresponding to the plurality of gate patterns PC, the first gate pillar PCP1, and the second gate pillar PCP2 included in the plurality of gate electrode layers 150 are formed together, portions of the plurality of dummy gate structures DGC corresponding to the plurality of gate patterns PC are connected to portions of the plurality of dummy gate structures DGC corresponding to the first and second gate pillars PCP1 and PCP2 such that leaning may not occur in the plurality of dummy gate structures DGC and the plurality of gate patterns PC corresponding thereto. Therefore, the integrated circuit device 1 according to embodiments of inventive concepts may limit and/or prevent problems caused by leaning from occurring, and may increase the degree of integration.

FIG. 17 is a cross-sectional view illustrating an integrated circuit device according to embodiments of inventive concepts. FIG. 17 is a cross-sectional view taken along a portion corresponding to line Y1-Y1′ of FIG. 1A.

Referring to FIG. 17, the integrated circuit device 10 may include a single gate MOSFET including a plurality of fin-type active regions FB protruding upward from the main surface 102M of the substrate 102 in a vertical direction (Z direction) and extending in a first horizontal direction (X direction).

A plurality of trenches TREa defining a plurality of fin-type active regions FB may be formed in the substrate 102. Lower portions of sidewalls of the plurality of fin-type active regions FB may be covered with an element isolation film 118 filling the plurality of trenches TREa.

A plurality of gate electrode layers 150a may be disposed on the plurality of fin-type active regions FB. At least some of the plurality of gate electrode layers 150a may extend in a second horizontal direction (Y direction) crossing the first horizontal direction (X direction). At least a portion of the plurality of gate electrode layers 150a may overlap each of the plurality of fin-type active regions FB in a vertical direction (Z direction). A gate dielectric film 145a is formed between the fin-type active region FB and the gate electrode layer 150a. The gate dielectric film 145a and the gate electrode layer 150a may be made of the same material as the gate dielectric film 145 and the gate electrode layer 150 shown in FIGS. 16A to 16E, and in plan view, the gate dielectric film 145 and the gate electrode layer 150 may have the same shape.

A plurality of second contact plugs 194 may be connected to the plurality of gate electrode layers 150a. The second contact plug 194 may pass through the interlayer insulating film 174 and be connected to the gate electrode layer 150a.

The plurality of gate electrode layers 150a may be the plurality of gate patterns PC shown in FIGS. 1A to 1C. Other some of the plurality of gate electrode layers 150a may be dummy gate patterns DPCs shown in FIGS. 1A to 1C. Other some of the plurality of gate electrode layers 150a may be gate pillars PCP shown in FIGS. 1A to 1C. Other some of the plurality of gate electrode layers 150a may be at least one edge dummy pattern EDP shown in FIGS. 1A to 1C.

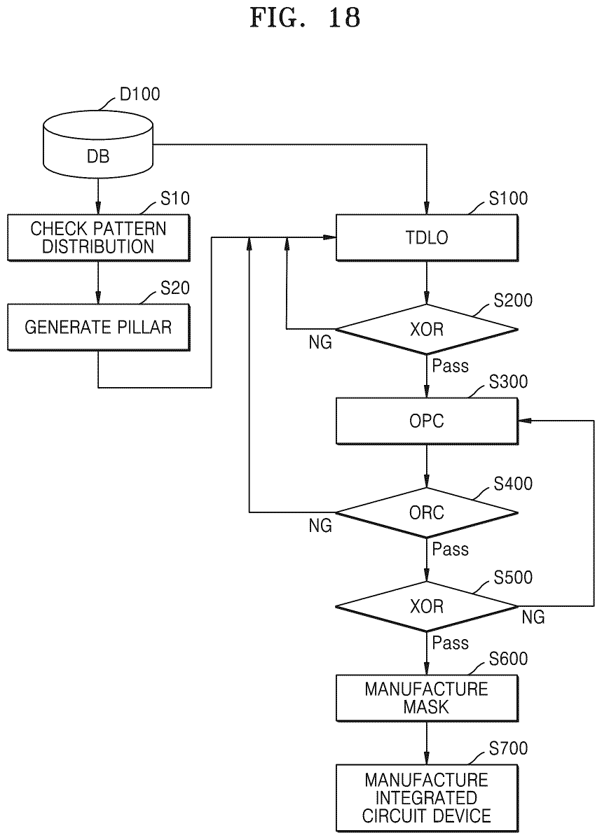

FIG. 18 is a flowchart illustrating a process of manufacturing an integrated circuit device according to embodiments of inventive concepts.

Referring to FIG. 18, after creating a design layout of an integrated circuit device, the design layout is stored in a database (DB) D100. For example, the design layout of the integrated circuit device stored in the DB (D100) may be generated in a Graphic Database II (GDSII) stream format (hereinafter referred to as GDSII). A design layout of the integrated circuit device may be, for example, a mask layout.

A distribution of a plurality of line patterns for forming a plurality of patterns included in the design layout of the integrated circuit device stored in the DB D100, for example, a plurality of gate patterns PC shown in FIGS. 1A to 4B, is checked in S10. After confirming the distribution of the plurality of patterns, a pillar is created (S20) at a required place in the design layout of the integrated circuit device, for example, at least one end of at least some of the plurality of patterns and added to the design layout of the integrated circuit device. The pillar may be a gate pillar PCP shown in FIGS. 1A to 4B.

A plurality of target patterns may be generated by performing a Table Driven Layout Operation (TDLO) procedure on the plurality of patterns included in the design layout of the generated integrated circuit device to which the pillar is added in S100. The plurality of target patterns may define a size of a pattern to be developed from a photoresist through a photolithography process (e.g., a photoresist pattern for generating the plurality of line patterns). That is, the plurality of target patterns may refer to a desired size of a photoresist pattern to be actually developed.

The plurality of patterns included in the design layout of the integrated circuit device to which the generated pillars are added may refer to the size of a final pattern to be formed on an etch target layer under the photoresist pattern, that is, the plurality of line patterns. A final pattern formed on the etch target layer may be smaller than the size of a photoresist pattern formed through a photolithography process. This is because the etching profile is inclined while patterning the etching target layer using the photoresist pattern as an etching mask. That is, the TDLO procedure for generating the plurality of target patterns is a process of correcting a difference between the size of a photoresist pattern formed through a photolithography process and the size of a final pattern formed in an etch target layer.

By comparing (XOR) the plurality of patterns included in the design layout of the integrated circuit device to which the generated pillars are added and the plurality of target patterns formed by performing the TDLO procedure, it is checked whether there is a missing target pattern among the plurality of target patterns corresponding to the plurality of patterns in S200. When there is no missing target pattern (Pass), optical proximity correction (OPC) is performed in S300, and when there is a missing target pattern (NG), the TDLO procedure is performed again in S100. The plurality of patterns included in the design layout of an integrated circuit device may be implemented on a silicon substrate using a photolithography process. In this case, OPC may be a technique for correcting a distortion phenomenon that may occur in a photolithography process. That is, through OPC, it is possible to correct distortion phenomena such as refraction or process effect that occur due to characteristics of light during exposure using the plurality of patterns included in the design layout of the integrated circuit device. While performing OPC, shapes and locations of the plurality of patterns included in the design layout of an integrated circuit device may be changed (biased).

After performing the OPC in S300, the verification of the OPC, for example, may be performed through optical rule check (ORC) in S400. The ORC may be performed by comparing a design layout of an integrated circuit device and a simulation contour. Comparison between the design layout of the integrated circuit device and the simulation contour may use edge placement errors (EPEs) that detect differences in edge positions.

By comparing (XOR) the plurality of patterns included in the design layout of the integrated circuit device to which the pillar is added and the OPC result, it is confirmed whether there is a missing pattern in the OPC process in S500. If there is a missing pattern (NG), the OPC is performed again in S300, and if there is no missing pattern (Pass), a mask is made in S600, and using the fabricated mask, the integrated circuit devices 1, 1a, 2, 3, and 10 described with reference to FIGS. 1A to 17 are manufactured in S700. The fabricated mask may be used as an etching mask for patterning the preliminary oxide film, the preliminary dummy gate layer, and the preliminary capping layer described in FIGS. 9 and 10 to form an oxide film D12, a dummy gate layer D14, and a capping layer D16. For example, the fabricated mask may be an EUV mask for an EUV lithography process.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts has been particularly shown and described with reference to embodiments thereof, it will be understood that various changes in form and details may be made therein without departing from the spirit and scope of the following claims.

What is claimed is:

1. An integrated circuit device comprising:
a substrate including a plurality of fin-type active regions, the plurality of fin-type active regions protruding from a surface of the substrate and extending in a first horizontal direction;
at least one gate pillar on the substrate and extending in the first horizontal direction; and
a plurality of gate groups arranged in a second horizontal direction on the plurality of fin-type active regions, wherein
the second horizontal direction is orthogonal to the first horizontal direction,
each of the plurality of gate groups comprises a plurality of gate patterns spaced apart from each other in the second horizontal direction,
each of the plurality of gate patterns extends in the second horizontal direction,
the plurality of gate patterns each include at least one dummy gate pattern on at least one end of a corresponding one of the plurality of gate groups in the second horizontal direction, and
the at least one dummy gate pattern is in contact with and connected to the at least one gate pillar.

2. The integrated circuit device of claim 1, wherein
the at least one dummy gate pattern in the plurality of gate groups is a plurality of dummy gate patterns, and
each of the plurality of dummy gate patterns has a same extension length in the second horizontal direction.

3. The integrated circuit device of claim 1, wherein
the plurality of gate patterns included in each of the plurality of gate groups and the at least one gate pillar include a same material.

4. The integrated circuit device of claim 1, wherein upper surfaces of the plurality of gate patterns included in each of the plurality of gate groups and an upper surface of each of the at least one gate pillar are located at a same vertical level.

5. The integrated circuit device of claim 1, wherein
each of the plurality of gate patterns has a first width in the first horizontal direction,
the at least one gate pillar has a second width in the second horizontal direction, and
the second width is greater than the first width.

6. The integrated circuit device of claim 5, further comprising:
at least one edge dummy pattern extending in the second horizontal direction on at least one side of the plurality of gate groups in the first horizontal direction, wherein
the at least one edge dummy pattern has a third width in the first horizontal direction, and
the third width is greater than the second width.

7. The integrated circuit device of claim 6, wherein
the at least one edge dummy pattern is spaced apart from each of the plurality of gate patterns and the at least one gate pillar.

8. The integrated circuit device of claim 6, wherein
the at least one edge dummy pattern is spaced apart from the plurality of gate patterns, and
the at least one edge dummy pattern is connected to and in contact with the at least one gate pillar.

9. An integrated circuit device comprising:
a substrate including a plurality of fin-type active regions, the plurality of fin-type active regions protruding from a surface of the substrate and extending in a first horizontal direction;
a nanosheet stacked structure including a plurality of nanosheets extending parallel to upper surfaces of each of the plurality of fin-type active regions, the plurality of nanosheets respectively having channel regions at positions spaced apart from the upper surfaces of the plurality of fin-type active regions;
a first gate pillar and a second gate pillar on the substrate, the first gate pillar and the second gate pillar extending in the first horizontal direction and being spaced apart from each other in a second horizontal direction, the second horizontal direction being orthogonal to the first horizontal direction; and
a first functional block including a plurality of first gate patterns on the plurality of fin-type active regions, the plurality of first gate patterns being spaced apart from each other in the second horizontal direction between the first gate pillar and the second gate pillar and extending in the second horizontal direction, wherein
the plurality of first gate patterns including first dummy gate patterns contacting and connected to the first gate pillar and second dummy gate patterns contacting and connected to the second gate pillar.

10. The integrated circuit device of claim 9, wherein
the first gate pillar and the first dummy gate patterns include a same material and are integrally formed,
the second gate pillar and the second dummy gate patterns include are integrally formed, and
a material of the second gate pillar is the same as a material of the second dummy gate patterns.

11. The integrated circuit device of claim 9, wherein
the first dummy gate patterns have a same extension length in the second horizontal direction, and
the second dummy gate patterns have equal extension lengths in the second horizontal direction.

12. The integrated circuit device of claim 9, further comprising:
a third gate pillar on the substrate, the third gate pillar extending in the first horizontal direction and being spaced apart from the second gate pillar in the second horizontal direction; and
a second functional block including a plurality of second gate patterns on the plurality of fin-type active regions, the plurality of second gate patterns being spaced apart from each other in the second horizontal direction between the second gate pillar and the third gate pillar and each extending in the second horizontal direction, wherein
the plurality of second gate patterns comprise third dummy gate patterns in contact with and connected to the second gate pillar and fourth dummy gate patterns in contact with and connected to the third gate pillar.

13. The integrated circuit device of claim 12, wherein the second dummy gate patterns, the second gate pillar, and the third dummy gate patterns include a same material and are integrally formed.

14. The integrated circuit device of claim 12, further comprising:
at least one first edge dummy pattern extending in the second horizontal direction on at least one side of the plurality of first gate patterns in the first horizontal direction; and
at least one second edge dummy pattern extending in the second horizontal direction on at least one side of the plurality of second gate patterns in the first horizontal direction, wherein
the at least one first edge dummy pattern and the at least one second edge dummy pattern are spaced apart from each other in the second horizontal direction and aligned with each other in the second horizontal direction.

15. The integrated circuit device of claim 14, wherein
each of the plurality of first gate patterns and the plurality of second gate patterns has a first width in the first horizontal direction,
each of the first gate pillar, the second gate pillar, and the third gate pillar has a second width in the second horizontal direction, and
the second width is greater than the first width.

16. The integrated circuit device of claim 15, wherein
each of the at least one first edge dummy pattern and the at least one second edge dummy pattern has a third width in the first horizontal direction, and
the third width is greater than the second width.

17. The integrated circuit device of claim 14, wherein,
in a plan view, the first gate pillar has a round portion at a corner opposite the first dummy gate patterns among two corners of an end of the first gate pillar facing the at least one first edge dummy pattern.

18. An integrated circuit device comprising:
a substrate including a plurality of fin-type active regions, the plurality of fin-type active regions protruding from a surface of the substrate and extending in a first horizontal direction;
a nanosheet stacked structure including a plurality of nanosheets extending parallel to upper surfaces of each of the plurality of fin-type active regions, and the plurality of nanosheets having channel regions at positions spaced apart from the upper surfaces of the plurality of fin-type active regions;
a first gate pillar and a second gate pillar on the substrate, the first gate pillar and the second gate pillar extending in the first horizontal direction and being spaced apart from each other in a second horizontal direction, the second horizontal direction orthogonal to the first horizontal direction;
a plurality of gate groups arranged in the second horizontal direction on the plurality of fin-type active regions, the plurality of gate groups including a plurality of gate patterns spaced apart from each other in the second horizontal direction between the first gate pillar and the second gate pillar, and the plurality of gate patterns extending in the second horizontal direction; and
a first edge dummy pattern and a second edge dummy pattern extending in the second horizontal direction at both sides of the plurality of gate groups in the first horizontal direction, wherein
in each of the plurality of gate groups, the plurality of gate patterns include a first dummy gate pattern and a second dummy gate pattern, the first dummy gate pattern being connected to and in contact with the first gate pillar to form an integral body, and the second dummy gate pattern being integrally connected to and in contact with the second gate pillar,
both ends of each of the plurality of gate groups in the second horizontal direction include the first dummy gate pattern,
each of the plurality of gate patterns has a first width in the first horizontal direction,
each of the first gate pillar and the second gate pillar has a second width in the second horizontal direction, and
the second width is greater than the first width.

19. The integrated circuit device of claim 18, wherein
the first edge dummy pattern and the second edge dummy pattern are spaced apart from each of the plurality of gate patterns, the first gate pillar, and the second gate pillar included in the plurality of gate groups,
each of the first edge dummy pattern and the second edge dummy pattern has a third width in the first horizontal direction, and
the third width is greater than the second width.

20. The integrated circuit device of claim 18, wherein
upper surfaces of the plurality of gate patterns, the first gate pillar, the second gate pillar, the first edge dummy pattern, and the second edge dummy pattern included in each of the plurality of gate groups are at a same vertical level and include a same material.
